(19) United States
(12) Patent Application Publication
(10) Pub. No.: US 2014/0338723 A1
(43) Pub. Date: Nov. 20, 2014

(54) System and Method for Periodic Solar Module Adjustment

(71) Applicant: Michael Patrick Flynn, Durango, CO (US)

(72) Inventor: Michael Patrick Flynn, Durango, CO (US)

(21) Appl. No.: 13/896,329

(22) Filed: May 17, 2013

(51) Int. Cl. H01L 31/052

(52) U.S. Cl. CPC H01L 31/052
USPC 136/246

(57) ABSTRACT

An adjustable solar module system includes a solar module configured for use with an electronic information system. The solar module has incremental settings for the horizontal and vertical positioning of the solar panels. The electronic information system includes a database that communicates with a user device (e.g. cell phone or computer) via a communications network. The system receives the user's GPS coordinates via the user's device. Based on the location, and the date, the system retrieves the position of the sun from the database. The sun's position is translated into horizontal and vertical coordinates that are then translated into the appropriate horizontal and vertical settings found on the solar module. The horizontal and vertical settings are then transmitted to the user's device to enable the user to make the appropriate adjustments.

### RELATED U.S. APPLICATION DATA

This application claims priority to Provisional Application No. 61/650,477, filed May 23, 2012.

### FIELD OF THE INVENTION

The present invention relates to solar modules, in particular, a method for adjustment of solar module.

### BACKGROUND OF THE INVENTION

Solar power has become increasingly popular and economical for both residential and commercial applications. Solar modules rely on solar energy in the form of sunlight, with energy collection being proportional to exposure of the solar cells (i.e. solar panels) to direct sunlight. As a result, it is desirable to optimize the position of the solar panels to the position of the sun. However, the movement of the sun is complex and typical users not having specialized knowledge and instruments are unable to make the proper adjustments to optimise energy collection. In particular, the manual adjustment of solar panels on solar modules is problematic because the layman is unable to determine the proper horizontal and vertical position of the panels that will optimize the capture of sunlight and electricity production throughout the year. While solar modules with automatic sun tracking hardware and software are commercially available, such systems are expensive and cost-prohibitive for many residential and commercial applications. The solar module system of the present invention overcomes the challenges of existing systems that are costly or unsuitable for use by the general consumer.

### SUMMARY OF THE INVENTION

An adjustable solar module system includes a solar module configured for use with an electronic information system. The solar module has incremental settings for the horizontal and vertical positioning of the solar panels. The electronic information system includes a database that communicates with a user device (e.g. cell phone or computer) via a communications network. The system receives the user's GPS coordinates via the user's device. Based on the location, and the date, the system retrieves the position of the sun from the database. The sun's position is translated into horizontal and vertical coordinates that are then translated into the appropriate horizontal and vertical settings found on the solar module. The horizontal and vertical settings are then transmitted to the user's device to enable the user to make the appropriate adjustments. The system is designed to allow a novice user of the solar module a simple means of initial set-up and periodic adjustment of the solar panels.

### BRIEF DESCRIPTION OF THE DRAWINGS

FIG. 1 is a system diagram showing the overall operation of the system including database, communications system, and user device.

FIG. 2 is a flow chart illustrating the method by which the present invention provides horizontal and vertical adjustment of solar modules.

FIG. 3 is a flow chart illustrating the method by which the database determines horizontal and vertical settings in response to a user position.

FIG. 4 illustrates the horizontal adjustment settings of a solar module configured to work with the method of the present invention.

FIG. 5 illustrates the vertical adjustment settings of a solar module configured to work with the method of the present invention.

FIG. 6 illustrates the horizontal rotation of a solar module from one setting to a subsequent setting.

### DETAILED DESCRIPTION

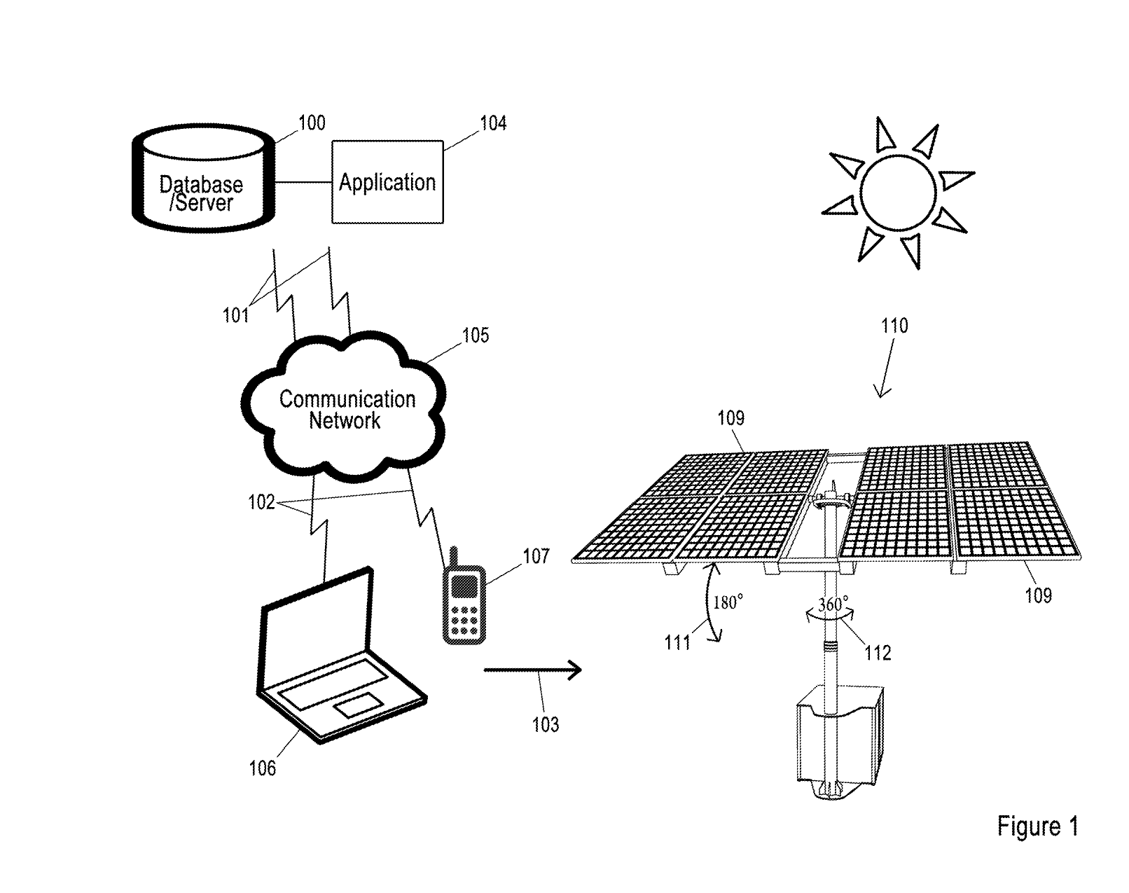

FIG. 1 is a diagram showing the overall components and operation of the solar module adjustment system in accordance with the present invention. The system includes an electronic information system comprising an application 104 running on a database/server 100 that utilizes a communications network 105 to communicate with a user device (e.g. laptop 106 and cell phone 107). The communications network 105 can be comprised of wireless cellular network and/or intemet connection. The output of the electronic information system, i.e. adjustment instruction 102, is transmitted to the user device. The adjustment instruction includes a horizontal setting number and a vertical setting number that correspond to the horizontal rotation 112 and vertical rotation 111 of the solar panels 109 of the solar module 110. The user adjusts the solar module accordingly to the adjustment instruction 102. The process is repeated periodically as desired to optimize the positioning of the solar panels. The system is initially calibrated by transmitting the position of the solar module to the electronic information system by using the automatic GPS functionality of the user device (e.g. cell phone 106) or by manually entering the GPS coordinates into the user device. As shown in FIG. 1, exemplary solar module 110, the solar panel 109 has 360° of horizontal rotation and 180° of vertical rotation.

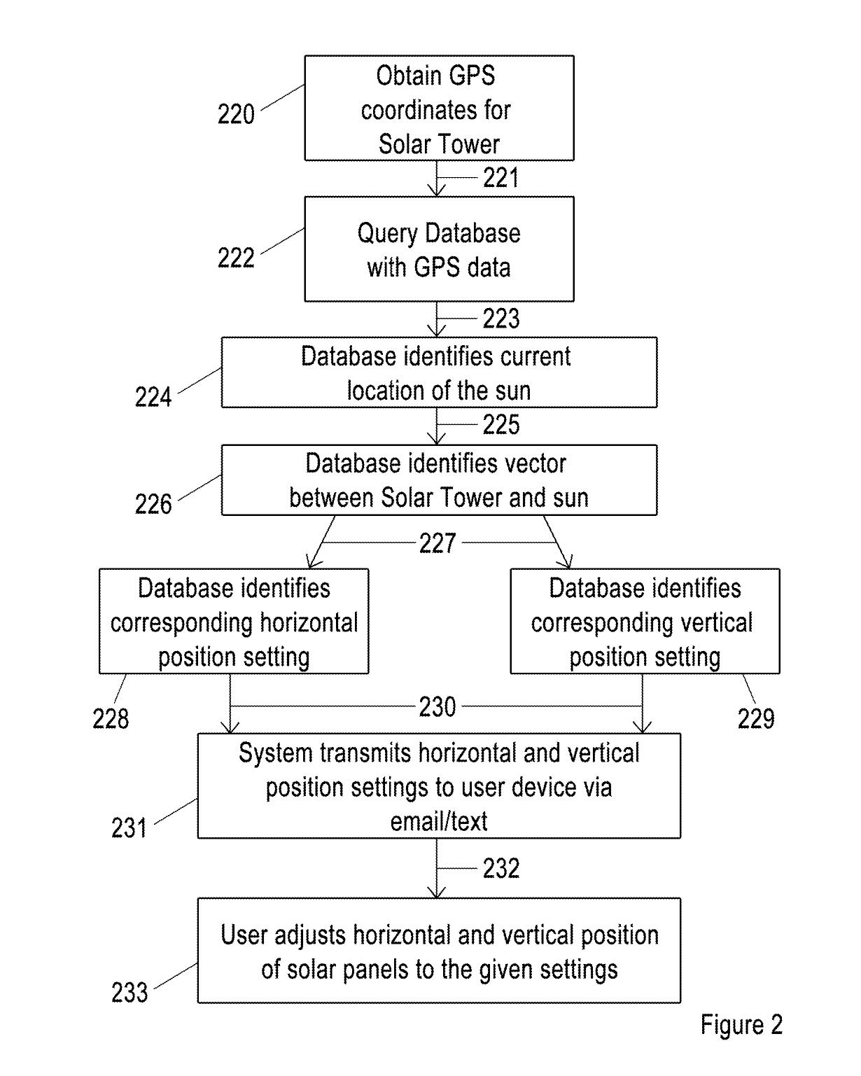

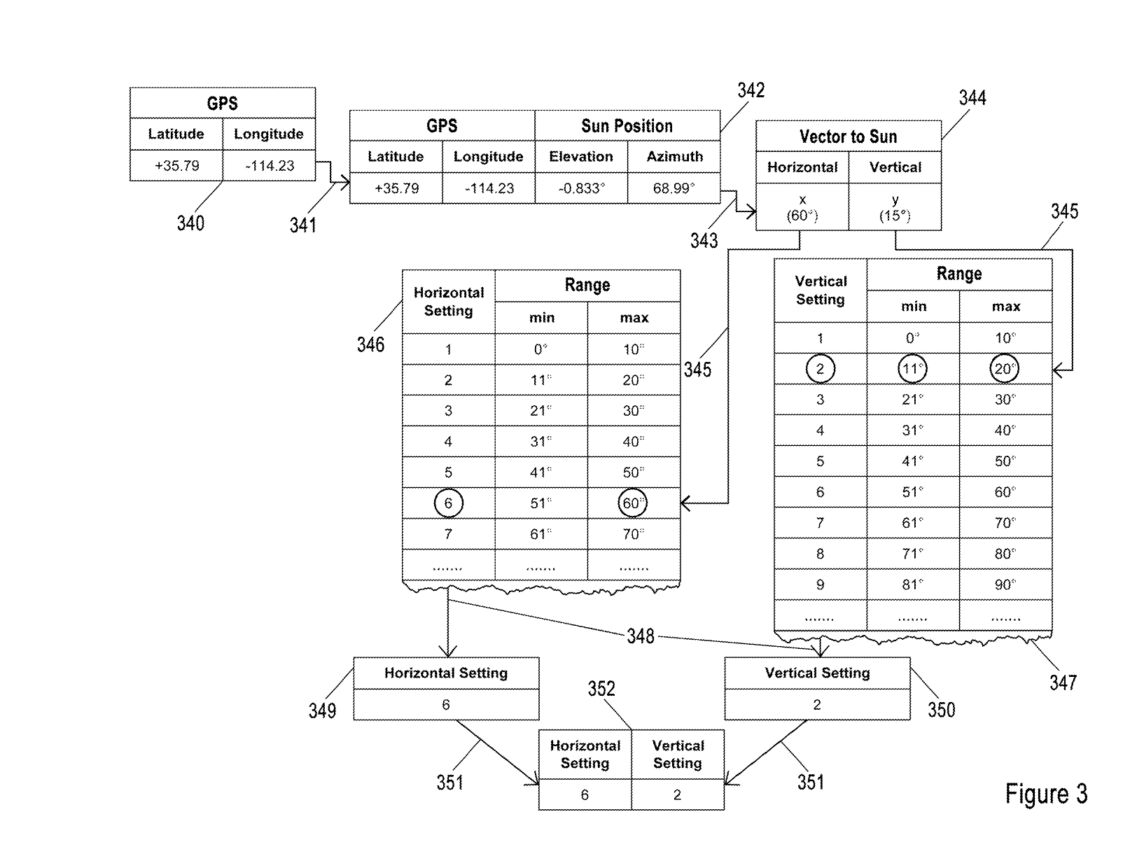

The database contains a system of data tables that are cross-referenced and correlated to provide the proper solar tower adjustment settings based on the GPS coordinates of the solar module as summarized in FIG. 2 and FIG. 3. FIG. 2 is a flowchart showing the process by which the system of the present invention provides a user with simple instructions for positioning a solar module to optimize the collection of solar energy in accordance with the changing position of the sun. As an initial step, the solar module should be aligned with a benchmark point such as magnetic North. At step 220, the system obtains global position system (“GPS”) coordinates that represent the location of the solar module from the user via the user's electronic device (e.g. cell phone or laptop computer). This sets the location of the solar module, which is the basis for the system's subsequent determinations. The GPS coordinates can be transmitted by the functionality of the user device itself (i.e. cell phone or tablet), via a smart phone application (i.e. “mobile app”), or via a web-based interface (i.e. website) that can be accessed via a mobile device or personal computer. The GPS coordinates (solar module location) are transmitted via the communications network as known in the art and used to query the database. At step 222 the database is queried with the GPS coordinates. At step 224, the database identifies the current position of the sun.

The database 224 contains positional data for the sun at various points in the solar cycle (e.g. the daily position of the sun through the year). Because re-adjustment of a solar module is only warranted when the position of the sun has changed an appreciable amount, the database 224 need not have the sun's position for every minute or hour of everyday. The goal is to track the sun's position during peak energy collection times and provide solar module adjustment information at reasonable intervals that do not needlessly burden the user for only minimal or unnoticeable gains in energy collection. Moreover, it would be impractical to have a solar module with a high number (e.g. 100+) positional settings. Therefore, for example, the database 224 need only contain positional data for the sun on a daily or weekly basis, corresponding to a daily or weekly adjustment frequency.

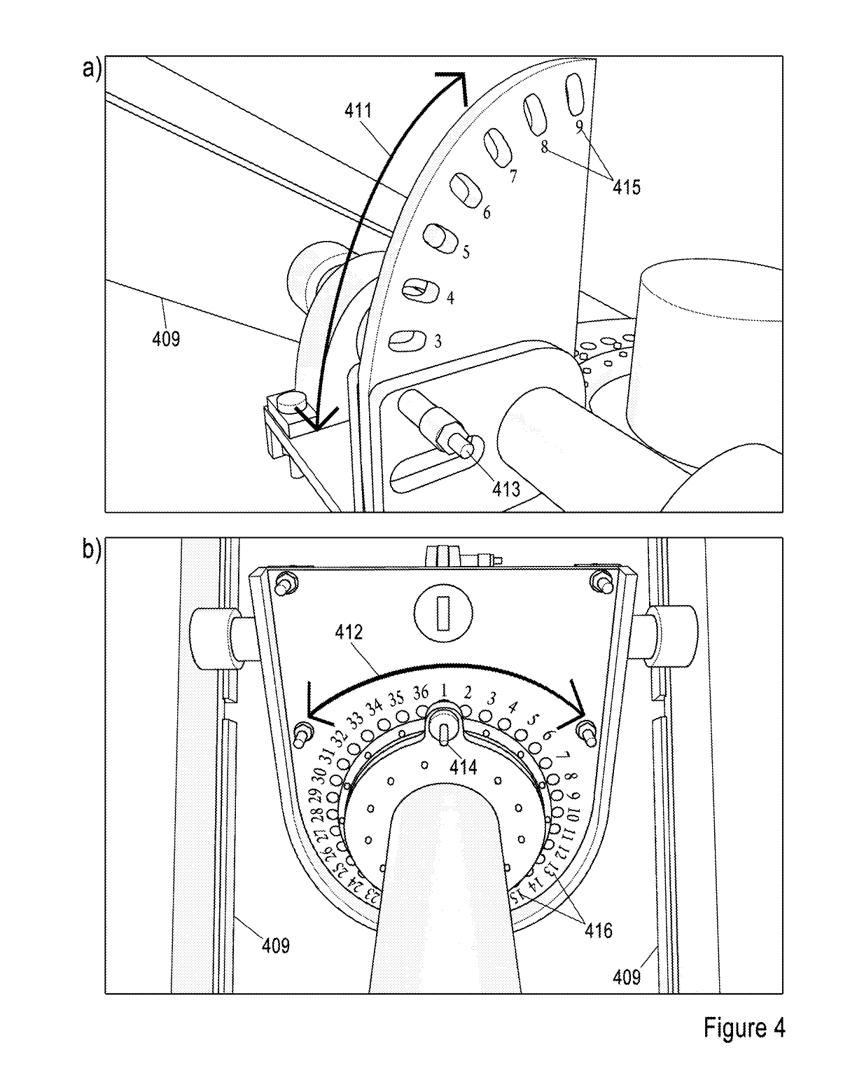

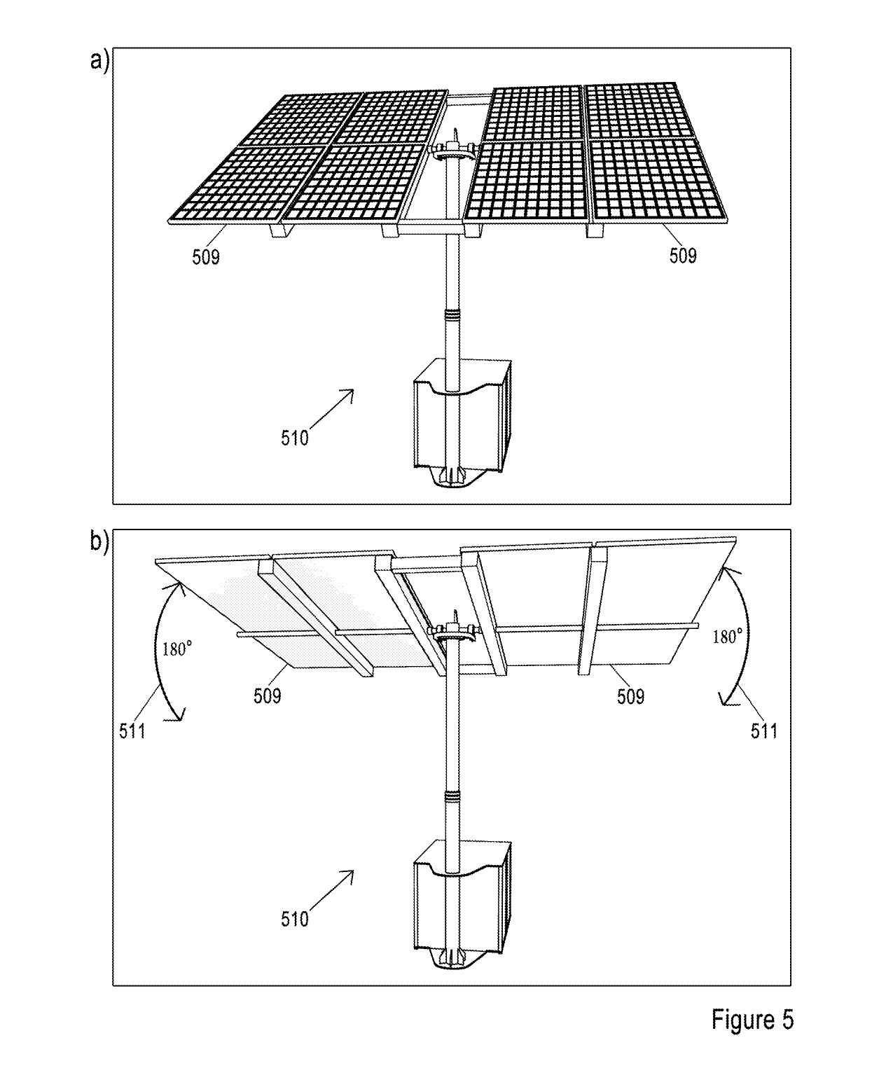

At step 226, the database compares the solar module location to the location of the sun, and determines the directional vector (“sun vector”) between the two points. This vector has a horizontal and vertical component and points from the solar module to the sun's current position. At steps 228 and 229, the sun vector is separated into its horizontal and vertical components, respectively. At step 228, the horizontal component of the sun vector is correlated with a horizontal position setting. Similarly, at step 229, the vertical component of the sun vector is correlated with a vertical position setting. The horizontal and vertical settings are in the form of integer numerals (e.g. 1, 2, 3, 4, 5 . . . ) corresponding to the incremental settings on the horizontal and vertical rotation mechanisms of the adjustment positions on the solar tower (as shown on FIGS. 4 and 5). The horizontal and vertical position settings are then transmitted to the user device via email, SMS/MMS text message, or web interface at step 231. The setting instructions could be sent daily, weekly, monthly, or based on any other desired frequency. Finally, at step 233, the user places the horizontal rotation of the solar module to the given horizontal setting and places the vertical rotation of the solar module to the given the vertical setting.

FIG. 3 is a flow chart representing the process by which the system determines the optimal horizontal and vertical position of the solar module based on given GPS coordinates. The process generally involves the correlation of data tables stored in the database. The database contains data table for the sun's position for different days of the year, among other information. At step 340, the GPS coordinates (latitude, longitude) serve a data inputs (x, y) that represent the location of the solar module. The process then retrieves the current position of the sun from data tables that contain the sun's location (e.g. elevation, azimuth) for every day of the year or other time interval. The GPS coordinates are then compared to the current sun position in table 342. This comparison yields (either by formulaic calculation or lookup table) a vector between the position of the solar module and the position of the sun (i.e. “sun vector”). Next, in table 344, this sun vector is separated into its horizontal and vertical components.

The horizontal component of the sun vector is compared to the table 346 that contains a series of horizontal settings that correspond to rotation ranges (degrees). The number of settings depends on the rotational capability of the solar module and the size of the ranges (which is arbitrary). For example, if the solar module is capable of 360 degrees of horizontal rotation, then the ranges in table 346 would go from zero to 360. The number of settings multiplied by the size of the range equals 360 degrees. In the exemplary table 346, the range is set at 10 degrees, which yields 36 settings (e.g. 36 settings*10 degrees=360 degrees). However, only the first seven settings are shown in table 346. The solar module would therefore have 36 horizontal position settings (i.e. horizontal rotation). In the example shown, the horizontal component of the sun vector is 60 degrees, which corresponds to setting number 6, which has a range of 51 to 60 degrees. The use of 10 degree increments between settings (i.e. range of 10 degrees per setting) is only exemplary and smaller or larger increments can be used.

Similarly, the vertical component of the sun vector is compared to the table 347 that contains a series of vertical settings that correspond to rotation ranges (degrees). As with table 346, the settings of table 347 have a range of 10 degrees (i.e. are separated by 10 degrees). However, only the first nine settings are shown in table 347. In the example shown, the sun vector has a vertical component of 15 degrees which corresponds to setting number 2, which has a range from 11 to 20 degrees. At step 351, the horizontal and vertical settings are combined and can be transmitted to the user device via the communications network. In the example of FIG. 3, the user is sent a message with the instruction “(6, 2)” which tells the user to put the horizontal rotation in setting number 6 and the vertical rotation in setting number 2.

FIGS. 4A and 4B show exemplary adjustment mechanisms on a solar module that are configured to work with the present adjustment method. The adjustment mechanisms shown in FIG. 4 are only exemplary and other mechanisms (manual or motorized) and setting increments could be used in accordance with the present invention. FIG. 4A shows an exemplary vertical rotation mechanism on a solar module, which rotates the solar panels in a plane perpendicular to the horizontal/ground plane as indicated by the curved arrow 411. Vertical settings 3 through 9 are shown, which correspond to a series of pin holes 415 that lock the vertical rotation into place in conjunction with locking pin 413. FIG. 4B shows an exemplary horizontal rotation mechanism on a solar module which rotates the solar panels in a plane parallel to the horizontal/ground plane as indicated by the curved arrow 412. Horizontal settings 1 through 36 are shown, which correspond to a series of pin holes 416 that lock the vertical rotation into place in conjunction with locking pin 414. The 36 horizontal settings in this example are separated by 10 degrees, totaling a 360 degrees of rotation.

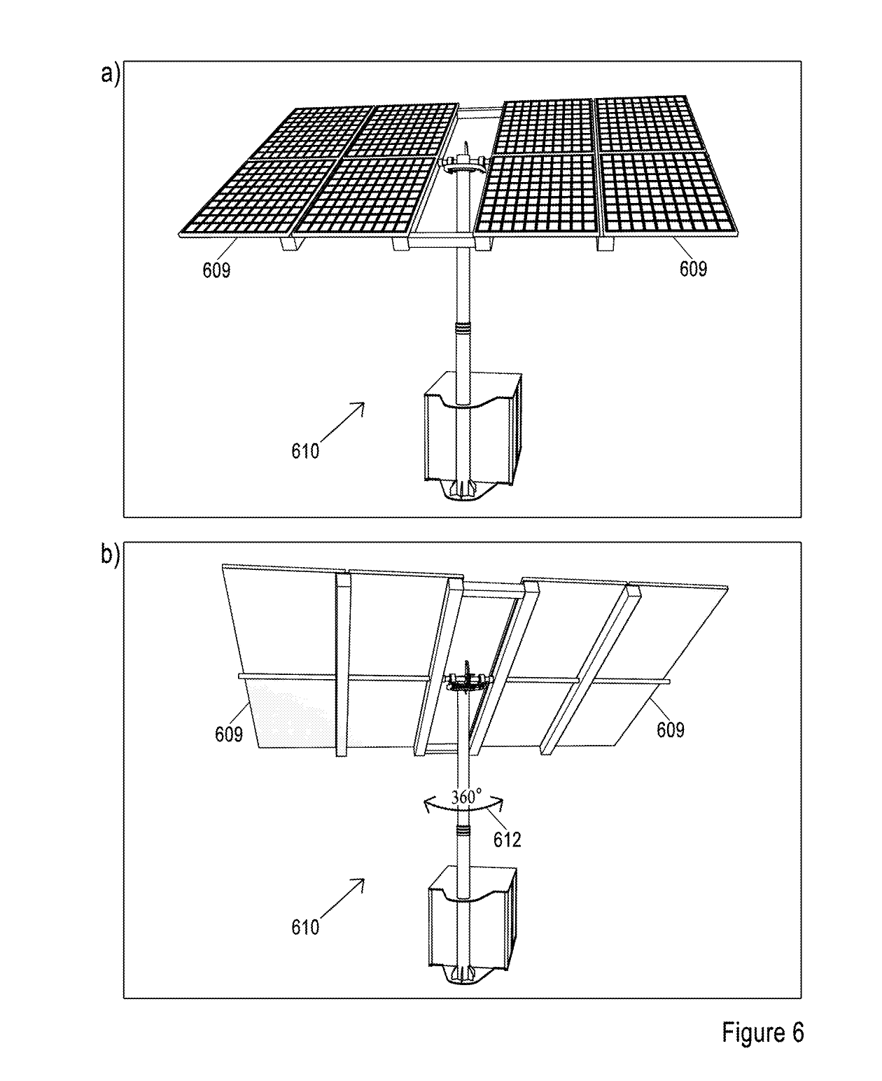

FIGS. 5A and 5B show an exemplary solar module 510 having solar panels 509 that are being vertically rotated as indicated by the curved arrows 511. The vertical rotation corresponds with the vertical adjustment settings shown in FIG. 4A. The vertical position settings 415 in FIG. 4A correspond to the vertical settings shown in data table 347. Similarly, the horizontal position settings 416 in FIG. 4B correspond to the horizontal settings shown in data table 346. FIGS. 6A and 6B show an exemplary solar module 610 having solar panels 609 that are being horizontally rotated as indicated by the curved arrows 612. The horizontal rotation corresponds with the horizontal adjustment settings shown in FIG. 4B.

As described above, the present invention provides a simple and inexpensive means to allow a consumer having no technical knowledge or equipment to periodically adjust their solar module in order to optimize the collection of solar energy in accordance with the movement of the sun. While there have been described herein what are considered to be preferred and exemplary embodiments of the present invention, other modifications of the invention shall be apparent to those skilled in the art from the teachings herein. For example, the relative dimensions of the device may be altered while keeping within the spirit and teachings of the invention. It is therefore desired to be secured, in the appended claims all such modifications as fall within the spirit and scope of the invention.

What is claimed is:

1. A method for providing simplified instructions for positioning a solar module comprising:
receiving GPS coordinates for the solar module;
identifying the current position of sun;
determining a sun vector that points from the solar module to the position of the sun;
separating the sun vector into horizontal and vertical components;
determining a horizontal position setting that corresponds to the horizontal component of the sun vector, said horizontal position setting corresponding to a horizontal setting on the solar module;
determining a vertical position setting that corresponds to the vertical component of the sun vector said horizontal position setting corresponding to a vertical setting on the solar module;
transmitting the settings to a user device to allow the user to adjust the horizontal and vertical position of the solar module in accordance with the settings.

2. The method of claim 1 wherein each horizontal setting is separated by 10 degrees of solar panel rotation.

3. The method of claim 1 wherein the user device is a Smartphone, tablet, or personal computer.

4. The method of claim 1 wherein the transmission is carried out via a SMS/MMS text message to a user Smartphone.

5. The method of claim 1 wherein the transmission is carried out via an email message to a user device.

6. The method of claim 1 wherein the transmission is carried out via an application alert, said application running on a Smartphone.

7. A solar module having horizontal and vertical rotational positions configured for use with the method of claim 1.

8. The method of claim 1 wherein the horizontal and vertical position settings are integers.

9. A system for providing solar module adjustment information to a user, comprising:
A database containing data of the sun's position throughout a solar cycle;
an application running on a database;
a user device;
a communication network allowing for the transmission of data to and from the application;
wherein the application is configured to receive GPS coordinates from the user device and transmit solar module adjustment information to the user device;
a solar module having solar panels, the solar panels having positional settings configured for use with the adjustment information provided by the application

10. The system of claim 9 wherein the adjustment information comprises a horizontal setting corresponding to the horizontal angle of the solar panels, and a vertical setting corresponding to the vertical angle of the solar panels.

11. The system of claim 9 wherein the user device is a Smartphone, tablet, or personal computer.

12. The method of claim 9 wherein the solar module adjustment information is transmitted via SMS/MMS text message to a user Smartphone.

13. The method of claim 9 wherein the solar module adjustment information is transmitted to the user device via an email message.

14. The method of claim 9 wherein the solar module adjustment information is transmitted via an application alert, said application running on a Smartphone.

15. The method of claim 9 wherein the solar module adjustment information is in the form of a pair of integers.
